(19) United States
(12) Patent Application Publication
(10) Pub. No.: US 2024/0265860 A1
(43) Pub. Date: Aug. 8, 2024

(54) PIXEL ARRANGEMENT STRUCTURE, METAL MASK AND ORGANIC LIGHT-EMITTING DISPLAY APPARATUS

(71) Applicant: Everdisplay Optronics (Shanghai) Co.,Ltd., Shanghai (CN)

(72) Inventors: Wei SANG, Shanghai (CN); Jun HU, Shanghai (CN); Kaikai CHEN, Shanghai (CN); Danfeng PU, Shanghai (CN)

(73) Assignee: Everdisplay Optronics (Shanghai) Co.,Ltd., Shanghai (CN)

(21) Appl. No.: 18/040,832

(22) PCT Filed: Aug. 19, 2021
(86) PCT No.: PCT/CN2021/113476

§ 371 Date: Feb. 7, 2023

(30) Foreign Application Priority Data
May 19, 2021 (CN) 202110544950.0
Aug. 6, 2021 (CN) 202110900469.0

(51) Int. Cl. G09G 3/3216; H10K 59/35

(52) U.S. Cl. CPC G09G 3/3216; H10K 59/353; G09G 2320/0233; G09G 2320/0242; G09G 2320/0626; G09G 2354/00

(57) ABSTRACT

Provided in the present application are a pixel arrangement structure, a metal mask and an organic light-emitting display apparatus. The pixel arrangement structure comprises a plurality of pixel units, which are arranged in an array in order, wherein each pixel unit comprises a first sub-pixel, a second sub-pixel, and two third sub-pixels having the same area, the two third sub-pixels having the same area are arranged in the same row, the first sub-pixel and the second sub-pixel are arranged in another row that is adjacent thereto, and the third sub-pixels having the same area and at least one third sub-pixel that is adjacent thereto correspond to the same opening region of the metal mask.

### TECHNICAL FIELD

The present application relates to the field of display technology, and particularly, to a pixel arrangement structure, a metal mask and an organic light emitting display apparatus.

### BACKGROUND

Compared with many display apparatuses, Organic Light Emitting Display (OLED) has many advantages such as all-solid-state, self-emitting, wide viewing angle, wide color gamut, fast response, high luminous efficiency, high brightness, high contrast, ultra-thin and ultra-light, low power consumption, wide operating temperature range, the ability to produce large size and flexible panels, and simple manufacturing process, etc., which can achieve a truly flexible display and best meet people's requirements for future displays.

The manufacturing process of OLED usually adopts Fine Metal Mask (FMM) to prepare red, green and blue light-emitting layers, which constitute red (R), green (G) and blue (B) sub-pixels, and the three sub-pixels of RGB are arranged repeatedly in order as a combined unit. However, in the production process of FMM, the opening region of the sub-pixel is limited since a certain amount of raw material needs to be reserved as a bridging part (Rib) between individual opening regions, which affects the aperture ratio of pixels, and in turn adversely affects the brightness and service life of the entire display panel, making it difficult to improve the brightness and service life of the display panel.

Based on this, how to solve the problem that the display brightness and service life of the existing organic light emitting display apparatus are difficult to be improved has become a technical problem to be solved urgently by those skilled in the art.

### SUMMARY

In view of this, the present application provides a pixel arrangement structure, a metal mask, and an organic light emitting display apparatus, so as to solve the problem of difficulty in improving the display brightness and service life of the organic light emitting display apparatus in the related art.

In order to solve the above technical problem, the present disclosure provides a pixel arrangement structure, and the pixel arrangement structure includes: a plurality of pixel units, where the plurality of pixel units are arranged in an array in sequence, and each pixel unit includes one first sub-pixel, one second sub-pixel and two third sub-pixels with equal area, where the two third sub-pixels with equal area are arranged in the same row and there is a first spacing between the two third sub-pixels, where the first sub-pixel and the second sub-pixel are arranged in another adjacent row and there is a second spacing between the first sub-pixel and the second sub-pixel;
where the first spacing is smaller than the second spacing, the two third sub-pixels with equal area and at least one third sub-pixel adjacent thereto correspond to a same opening region of a metal mask, the third sub-pixels corresponding to the same opening region of the metal mask are one group of the third sub-pixels, and a spacing between adjacent two groups of the third sub-pixels is greater than the second spacing.

Optionally, a perpendicular bisector of a line connecting centers of the two third sub-pixels with equal area does not overlap with a perpendicular center line of the pixel unit, and the spacing between the two third sub-pixels with equal area are all consistent; and
the third sub-pixels are all arranged in mirror symmetry in two laterally adjacent pixel units.

Optionally, in the pixel arrangement structure, in a same row of pixel units, the two third sub-pixels with equal area and two third sub-pixels adjacent thereto correspond to the same opening region of the metal mask.

Optionally, in the pixel arrangement structure, in the same row of pixel units, the first sub-pixels and the second sub-pixels are arranged alternately and repeatedly; or
in the two laterally adjacent pixel units, the first sub-pixels and the second sub-pixels are all arranged in mirror symmetry.

Optionally, in the pixel arrangement structure, in two adjacent rows of pixel units, the two third sub-pixels with equal area and six third sub-pixels adjacent thereto correspond to the same opening region of the metal mask.

Optionally, in the pixel arrangement structure, the two laterally adjacent pixel units are both arranged in mirror symmetry, and two vertically adjacent pixel units are both arranged in mirror symmetry; or
the two laterally adjacent pixel units are both arranged in mirror symmetry, and one of the two vertically adjacent pixel units is arranged to overlap with the other pixel unit after being rotated by 180°.

Optionally, in the pixel arrangement structure, a perpendicular bisector of a line connecting centers of the two third sub-pixels with equal area overlap with a perpendicular center line of the pixel unit, and in two laterally adjacent pixel units, the spacing between the two third sub-pixels in one pixel unit is greater than the spacing between the two third sub-pixels in the other pixel unit.

Optionally, in the pixel arrangement structure, in a same row of pixel units, the two third sub-pixels with equal area and one or two third sub-pixels adjacent thereto correspond to the same opening region of the metal mask.

Optionally, in the pixel arrangement structure, a spacing between the first sub-pixel and the second sub-pixel, a spacing between the first sub-pixel and the third sub-pixel, and a spacing between the second sub-pixel and the third sub-pixel are all equal.

Optionally, in the pixel arrangement structure, the colors of the first sub-pixel, the second sub-pixel and the third sub-pixel are different from each other, and the first sub-pixel, the second sub-pixel and the third sub-pixel are respectively selected from any one of a red sub-pixel, a blue sub-pixel and a green sub-pixel.

Optionally, in the pixel arrangement structure, the third sub-pixel is the blue sub-pixel or the green sub-pixel.

Optionally, in the pixel arrangement structure, the pixel unit is a square, and the first sub-pixel, the second sub-pixel and the third sub-pixel are all rectangular, triangular, polygon or circle.

Optionally, in the pixel arrangement structure, a ratio of an area of the third sub-pixel to an area of the first sub-pixel is between 0.5 and 1.5, and a ratio of the area of the third sub-pixel to an area of the second sub-pixel is between 0.5 and 1.5.

Correspondingly, the present application also provides a metal mask, the metal mask includes: a substrate;
where the substrate is provided with a plurality of opening regions, the plurality of opening regions are arranged in sequence, and each opening region corresponds to one group of the third sub-pixels of the pixel arrangement structure as mentioned above, and each group of the third sub-pixels includes four third sub-pixels with equal area or eight third sub-pixels with equal area.

Optionally, in the metal mask, the plurality of opening regions are arranged side by side in both a row direction and a column direction; or
the plurality of opening regions are arranged side by side in the row direction, and are arranged in a staggered arrangement in the column direction.

Correspondingly, the present application also provides an organic light emitting display apparatus, the organic light emitting display apparatus includes the pixel arrangement structure as mentioned above.

Optionally, in the organic light emitting display apparatus, the two third sub-pixels of a same pixel unit are both driven by a same data signal line; or
the two third sub-pixels of the same pixel unit are respectively driven by two data signal lines.

In the pixel arrangement structure, the metal mask and the organic light emitting display apparatus provided by the present application, the number of sub-pixels is increased by splitting one of the sub-pixels of the pixel unit into two, and the distribution position of the sub-pixels in the pixel unit is adjusted to improve the display effect, and the display defects such as jaggies and black lines are effectively improved. Moreover, the corresponding metal mask can ensure the spacing between the openings with the same color by using the form of a shared opening region, thereby enhancing the strength of the metal mask, relieving the restriction of the manufacturing accuracy of the metal mask on the high-resolution screen, and improving the pixel aperture ratio. Thus, the display brightness and service life of the organic light emitting display apparatus are improved.

### BRIEF DESCRIPTION OF THE DRAWINGS

The accompanying drawings, which are incorporated in and constitute a part of this specification, illustrate embodiments consistent with the present application and are used in conjunction with the specification to explain the principles of the present application. Obviously, the drawings in the following description are only some embodiments of the present application. For those of ordinary skill in the art, other drawings can also be obtained from these drawings without paying creative effort.

FIG. 1 is a schematic structural diagram of a pixel arrangement structure according to a first embodiment of the present application;

FIG. 2 is a schematic structural diagram of a metal mask for evaporating a third sub-pixel according to the first embodiment of the present application;

FIG. 3 is a schematic structural diagram of a pixel arrangement structure according to a second embodiment of the present application;

FIG. 4 is a schematic structural diagram of a metal mask for evaporating a third sub-pixel according to the second embodiment of the present application;

FIG. 5 is a schematic structural diagram of an organic light emitting display apparatus using a single-line driving manner according to the second embodiment of the present application;

FIG. 6 is a schematic structural diagram of an organic light emitting display apparatus using a dual-line driving manner according to the second embodiment of the present application;

FIG. 7 is a schematic structural diagram of a pixel arrangement structure according to a third embodiment of the present application;

FIG. 8 is a schematic structural diagram of a pixel arrangement structure and a metal mask corresponding to its first sub-pixel according to the third embodiment of the present application;

FIG. 9 is a schematic structural diagram of a pixel arrangement structure and a metal mask corresponding to its second sub-pixel according to the third embodiment of the present application;

FIG. 10 is a schematic structural diagram of a pixel arrangement structure according to a fourth embodiment of the present application;

FIG. 11 is a schematic structural diagram of a pixel arrangement structure and a metal mask corresponding to its first sub-pixel according to the fourth embodiment of the present application;

FIG. 12 is a schematic structural diagram of a pixel arrangement structure and a metal mask corresponding to its second sub-pixel according to the fourth embodiment of the present application;

FIG. 13 is a schematic structural diagram of a pixel arrangement structure according to a fifth embodiment of the present application;

FIG. 14 is a schematic structural diagram of a pixel arrangement structure according to a sixth embodiment of the present application;

FIG. 15 is a schematic structural diagram of a metal mask for evaporating a third sub-pixel according to the sixth embodiment of the present application;

FIG. 16 is a schematic structural diagram of an organic light emitting display apparatus using a single-line driving manner according to the sixth embodiment of the present application;

FIG. 17 is a schematic structural diagram of a pixel arrangement structure and a metal mask corresponding to its first sub-pixel according to another embodiment of the present application;

FIG. 18 is a schematic structural diagram of a pixel arrangement structure and a metal mask corresponding to its second sub-pixel according to another embodiment of the present application;

FIG. 19 is a schematic structural diagram of a pixel arrangement structure and a metal mask corresponding to its first sub-pixel according to still another embodiment of the present application;

FIG. 20 is a schematic structural diagram of a pixel arrangement structure and a metal mask corresponding to its second sub-pixel according to still another embodiment of the present application.

### DETAILED DESCRIPTION

Exemplary implementation manners will now be described more comprehensively with reference to the accompanying drawings. However, the exemplary implementation manners may be implemented in various forms and should not be construed as being limited to the implementation manners set forth herein. Rather, these implementation manners are provided so that the present application will be thorough and complete, and the concept of the exemplary implementation manners may be comprehensively conveyed to those skilled in the art. The same reference numerals in the drawings denote the same or similar structures, and thus their repetitive descriptions will be omitted.

### First Embodiment

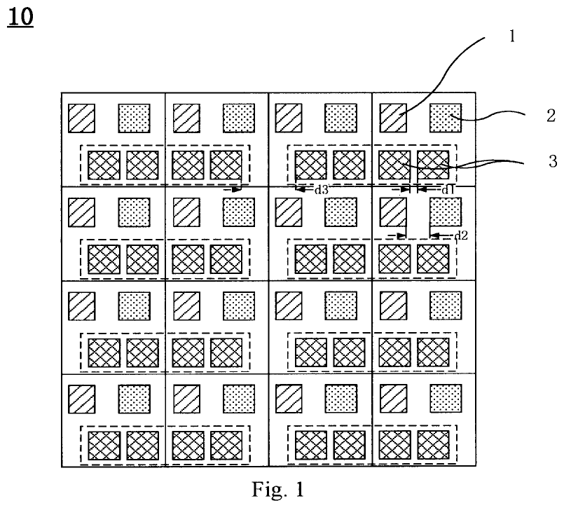

FIG. 1 is a schematic structural diagram of a pixel arrangement structure according to a first embodiment of the present disclosure. As shown in FIG. 1, the pixel arrangement structure 10 includes a plurality of pixel units (reference numerals are not shown in the figure), the plurality of pixel units are arranged in an array in sequence, and each pixel unit (shown by a single solid line box) includes a first sub-pixel 1, a second sub-pixel 2, and two third sub-pixels 3 with equal area, where the two third sub-pixels with equal area are arranged in the same row and there is a first spacing d1 between the two third sub-pixels 3, and the first sub-pixel 1 and the second sub-pixel 2 are arranged in another adjacent row and there is a second spacing d2 between the first sub-pixel 1 and the second sub-pixel 2; where the first spacing d1 is smaller than the second spacing d2, a perpendicular bisector of a line connecting centers of the two third sub-pixels 3 with equal area does not overlap with a perpendicular center line of the pixel unit, the third sub-pixels 3 are all arranged in mirror symmetry in two laterally adjacent pixel units, the two third sub-pixels 3 with equal area and two third sub-pixels 3 adjacent thereto correspond to a same opening region of the metal mask, the third sub-pixels 3 corresponding to the same opening region of the metal mask are one group of the third sub-pixels 3, and a spacing d3 between adjacent two groups of the third sub-pixels 3 is greater than the second spacing d2.

Specifically, the plurality of pixel units are arranged in an array in sequence and each pixel unit includes one first sub-pixel 1, one second sub-pixel 2 and two third sub-pixels 3 with equal area. Among the four sub-pixels, the two third sub-pixels 3 with equal area are arranged side by side, the first sub-pixel 1 and the second sub-pixel 2 are arranged side by side and located at the same side of the two third sub-pixels 3 with equal area.

As shown in FIG. 1, in each pixel unit, a preset distance is maintained between the first sub-pixel 1 and the second sub-pixel 2 and between the two third sub-pixels 3 with equal area, the spacing between the two third sub-pixels 3 with equal area is the first spacing d1, the spacing between the first sub-pixel 1 and the second sub-pixel 2 is the second spacing d2, and the first spacing d1 is smaller than the second spacing d2.

The pixel units are squares. The perpendicular bisector of the line connecting centers of the two third sub-pixels 3 with equal area does not overlap with the perpendicular center line of the pixel unit. That is, the center of the two third sub-pixels 3 with equal area deviates from the center of the corresponding pixel unit. The third sub-pixels are all arranged in mirror symmetry in two laterally adjacent pixel units. Therefore, the two third sub-pixels 3 of the pixel unit in the first column are relatively adjacent to the two third sub-pixels 3 of the pixel unit in the second column, the two third sub-pixels 3 of the pixel unit in the third column are relatively adjacent to the two third sub-pixels 3 of the pixel unit in the fourth column, and the two third sub-pixels 3 of the pixel unit in the second column are relatively far away from the two third sub-pixels 3 of the pixel unit in the third column.

Alternatively, the centers of the first sub-pixels 1 and the second sub-pixels 2 of the same row are on the same straight line, and the first sub-pixels 1 and the second sub-pixels 2 are equally spaced. Further, the spacings between adjacent different-color sub-pixels (including the spacing between the first sub-pixel 1 and the second sub-pixel 2, the spacing between the first sub-pixel 1 and the third sub-pixel 3, and the spacing between the second sub-pixel 2 and the third sub-pixel 3) are equal.

Continuing to refer to FIG. 1, in the row direction of the array, the first sub-pixels 1 and the second sub-pixels 2 are alternately and repeatedly arranged. The first sub-pixels 1 are arranged in a first sub-pixel column in the column direction, and the second sub-pixels 2 are arranged in a second sub-pixel column in the column direction. That is, the first sub-pixel 1 and the second sub-pixel 2 of one pixel unit in the two laterally adjacent pixel units are arranged in the same way as the first sub-pixel 1 and the second sub-pixel 2 of the other pixel unit in the two laterally adjacent pixel units. The third sub-pixels 3 are arranged in a third sub-pixel row in the row direction, and are arranged in a third sub-pixel column in the column direction. And the third sub-pixels 3 are all arranged in mirror symmetry in two laterally adjacent pixel units. For the sake of brevity, FIG. 1 only takes 4 rows and 4 columns of pixel units as an example.

The colors of the first sub-pixel, the second sub-pixel and the third sub-pixel are different from each other, and the first sub-pixel, the second sub-pixel and the third sub-pixel are respectively selected from any one of a red sub-pixel, a blue sub-pixel and a green sub-pixel.

In this embodiment, the first sub-pixel 1, the second sub-pixel 2 and the third sub-pixel 3 are a red sub-pixel, a green sub-pixel and a blue sub-pixel in sequence. In other embodiments, the first sub-pixel 1, the second sub-pixel 2 and the third sub-pixel 3 may be a red sub-pixel, a blue sub-pixel and a green sub-pixel in sequence, and may also be a blue sub-pixel, a green sub-pixel, and a red sub-pixel in sequence or other color combinations, which is not limited by the present application.

In this embodiment, the first sub-pixel 1, the second sub-pixel 2 and the third sub-pixel 3 are all rectangular. In other embodiments, the first sub-pixel 1, the second sub-pixel 2 and the third sub-pixel 3 may also be triangles, polygons, circles, ellipses or other shapes, which is not limited in the present application.

In this embodiment, the first sub-pixel 1 and the second sub-pixel 2 of each pixel unit are located above the two third sub-pixels 3 with equal area. In other embodiments, the first sub-pixel 1 and the second sub-pixel 2 of each pixel unit may also be located below the two third sub-pixels 3 with equal area.

In this embodiment, the ratio of the area of the third sub-pixel 3 to the area of the first sub-pixel 1 or the second sub-pixel 2 is between 0.5 and 1.5.

Continuing to refer to FIG. 1, the centers of the third sub-pixels 3 in the same row are on the same straight line. Moreover, in the same row of pixel units, the two third sub-pixels 3 with equal area and two third sub-pixels 3 with equal area adjacent thereto (i.e. one group of third sub-pixels) correspond to the same opening region of the metal mask (shown in the dashed box in the figure). Four third sub-pixels 3 corresponding to the same opening region of the metal mask belong to one group, and each group of third sub-pixels includes four third sub-pixels 3 arranged side by side. The spacing between adjacent two groups of third sub-pixels 3 (i.e. the spacing between the third sub-pixels groups) d3 is greater than the spacing between adjacent sub-pixels with different colors. The spacing between adjacent sub-pixels with different colors refers to a distance (i.e. the second spacing d2) between the directly adjacent first sub-pixel 1 and second sub-pixel 2, a distance between the directly adjacent first sub-pixel 1 and third sub-pixel 3, and the spacing between the directly adjacent second sub-pixel 2 and third sub-pixel 3 in the same row of pixel units, respectively.

Alternatively, the spacing between the first sub-pixel and the second sub-pixel, the spacing between the first sub-pixel and the third sub-pixel, and the spacing between the second sub-pixel and the third sub-pixel are all equal to the second spacing d2.

When actually preparing the OLED pixel array, the above d1, d2, and d3 all need to meet a certain process design requirement. For example, each distance meets the requirement of being greater than its minimum value.

In the related art, the pixel design of OLED usually uses three sub-pixels of red (R), green (G), and blue (B) as a combination unit for repeated arrangement and combination. The sub-pixels of three colors of R, G, and B in each combination unit are arranged in an inverted triangle (called Real arrangement), or in a staggered arrangement of positive triangles and inverted triangles (called Delta arrangement). However, the design with inverted triangular arrangement of sub-pixels of three colors of R, G, and B results in a relatively small overall light-emitting area of the display due to the non-dense arrangement of the three colors, which ultimately affects the service life of the product. For the design in which the sub-pixels of three colors of R, G, and B are arranged in a staggered arrangement of positive triangles and inverted triangles, although the three-color arrangement is in a form of dense arrangement, which can increase the overall light-emitting area of the display, the relative distribution position of the center of the sub-pixels of three colors of R, G, and B in the pixel unit will change. Since the human eye is most sensitive to green light, it may cause jagged display problems.

Correspondingly, if the conventional red, green and blue arrangement such as Real arrangement or Delta arrangement is adopted, the corresponding fine metal mask (FMM) needs to keep a certain amount of raw material as a bridge part (Rib) between each opening region during the fabrication process, resulting in limited opening region, which in turn affects the total aperture ratio, and ultimately makes it difficult to improve the display brightness and service life of the entire panel.

In this embodiment, the number of sub-pixels is increased by splitting one of the sub-pixels of the pixel unit into two, and the distribution position of the sub-pixels in the pixel unit is adjusted, therefore the display effect is improved, and the display defects such as jaggies and black lines are effectively improved.

It is known that when vapor deposition is performed using a metal mask, a shadow effect is generated due to the thickness of metal mask and vaporization angle matching. In the pixel arrangement structure 10 provided in this embodiment, since the third sub-pixels 3 may share the opening of the metal mask, the spacing d1 between the third sub-pixels 3 is not affected by the shadow effect. The spacing between the third sub-pixels 3 can be further reduced, thereby increasing the utilization rate of the corresponding space, and improving the aperture ratio.

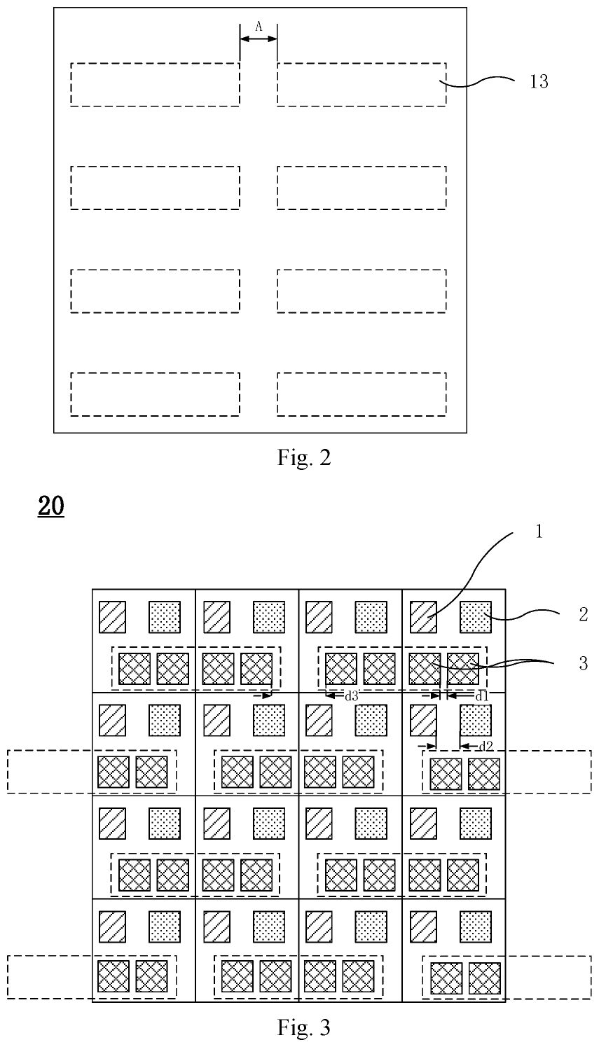

Correspondingly, the present disclosure also provides a metal mask. FIG. 2 is a schematic structural diagram of a metal mask according to a first embodiment of the present disclosure. As shown in FIG. 2, the metal mask includes: a substrate (reference numeral is not shown in the figure); the substrate is provided with a plurality of opening regions 13, the plurality of opening regions 13 are arranged in sequence, and each opening region 13 corresponds to one group of the third sub-pixels 3 of the pixel arrangement structure 10 as mentioned above, and each group of the third sub-pixels 3 includes four third sub-pixels 3 with equal area.

Specifically, the metal mask is used for evaporating the third sub-pixels 3, and the positions of the plurality of opening regions 13 provided on the metal mask are adapted to the arrangement positions of the third sub-pixels 3.

In this embodiment, the third sub-pixel 3 is a blue sub-pixel, that is, the metal mask is used for evaporating the blue sub-pixel. In other embodiments, the third sub-pixel 3 may also be a red sub-pixel or a green sub-pixel, that is, the metal mask is used for evaporating the red sub-pixel or the green sub-pixel.

In the fabrication of metal mask, the spacing between the openings with the same color is one of the key factors for affecting the strength of the metal mask. As shown in FIG. 2, in the metal mask provided in this embodiment, since four third sub-pixels with equal area share the same opening region 13, it is possible to ensure that the spacing A between the openings with the same color is large enough to reduce the number of the opening regions 13 without sacrificing the strength of the metal mask. In this way, the difficulty of preparing the mask is reduced, the restriction on the high-resolution screen due to the fabrication accuracy of the metal mask can be alleviated, thereby increasing the aperture ratio, and the pixel unit with relatively small size can be manufactured in the case that the process conditions are met. Therefore, the resolution of the organic light emitting display screen is improved, the service life of the organic light emitting display device can be long and the imaging effect is more delicate.

In this embodiment, the metal mask is a fine metal mask (FMM), and the plurality of opening regions 13 of the metal mask are arranged side by side in both a row direction and a column direction.

Correspondingly, the present disclosure also provides an organic light emitting display apparatus, and the organic light emitting display apparatus includes the pixel arrangement structure 10 as described above. For details, the above contents may be referred to, which will not be repeated here.

In the pixel arrangement structure 10, each third sub-pixels group includes four blue sub-pixels, and the four blue sub-pixels are formed by evaporation through the same slot (i.e. the opening region 13).

### Second Embodiment

FIG. 3 is a schematic structural diagram of a pixel arrangement structure according to a second embodiment of the present disclosure. As shown in FIG. 3, the pixel arrangement structure 20 includes a plurality of pixel units (the reference numeral is not shown in the figure), the plurality of pixel units are arranged in an array in sequence, and each pixel unit (shown by a single solid line box) includes one first sub-pixel 1, one second sub-pixel 2 and two third sub-pixels 3 with equal area, where the two third sub-pixels with equal area are arranged in the same row and there is a first spacing d1 between the two third sub-pixels 3, the first sub-pixel 1 and the second sub-pixel 2 are arranged in another adjacent row and there is a second spacing d2 between the first sub-pixel 1 and the second sub-pixel 2; where the first spacing d1 is smaller than the second spacing d2, a perpendicular bisector of a line connecting centers of the two third sub-pixels 3 with equal area does not overlap with a perpendicular center line of the pixel unit, the third sub-pixels 3 are all arranged in mirror symmetry in two laterally adjacent pixel units, the two third sub-pixels 3 with equal area and two third sub-pixels 3 adjacent thereto correspond to a same opening region of the metal mask, the third sub-pixels 3 corresponding to the same opening region of the metal mask are one group of the third sub-pixels 3, and a spacing d3 between adjacent two groups of the third sub-pixels 3 is greater than the second spacing d2.

Specifically, the plurality of pixel units are arranged in an array in sequence, in the row direction of the array, the first sub-pixels 1 and the second sub-pixels 2 are alternately and repeatedly arranged, the third sub-pixels 3 are arranged side by side, and the third sub-pixels are all arranged in mirror symmetry in two laterally adjacent pixel units. For the sake of brevity, FIG. 1 only takes 4 rows and 4 columns of pixel units as an example.

As shown in FIG. 3, in each pixel unit, the two third sub-pixels 3 with equal area are arranged side by side, the first sub-pixel 1 and the second sub-pixel 2 are arranged side by side and located at the same side of the two third sub-pixels 3 with equal area, and a preset distance is maintained between the first sub-pixel 1 and the second sub-pixel 2 and between the two third sub-pixels 3 with equal area. The spacing d1 between the two third sub-pixels 3 with equal area is smaller between the spacing d2 between the first sub-pixel 1 and the second sub-pixel 2.

Continuing to refer to FIG. 3, the pixel units are squares, the perpendicular bisector of the line connecting centers of the two third sub-pixels 3 with equal area does not overlap with the perpendicular center line of the pixel unit. The third sub-pixels are all arranged in mirror symmetry in two laterally adjacent pixel units. Therefore, the two third sub-pixels 3 of the pixel unit in the first column of odd-numbered rows are relatively adjacent to the two third sub-pixels 3 of the pixel unit in the second column of odd-numbered rows, the two third sub-pixels 3 of the pixel unit in the third column of odd-numbered rows are relatively adjacent to the two third sub-pixels 3 of the pixel unit in the fourth column of odd-numbered rows, and the two third sub-pixels 3 of the pixel unit in the second column of odd-numbered rows are relatively far away from the two third sub-pixels 3 of the pixel unit in the third column of odd-numbered rows. And the two third sub-pixels 3 of the pixel unit in the first column of even-numbered rows are relatively far away from the two third sub-pixels 3 of the pixel unit in the second column of even-numbered rows, the two third sub-pixels 3 of the pixel unit in the third column of even-numbered rows are relatively far away from the two third sub-pixels 3 of the pixel unit in the fourth column of even-numbered rows, and the two third sub-pixels 3 of the pixel unit in the second column of even-numbered rows are relatively adjacent to the two third sub-pixels 3 of the pixel unit in the third column of even-numbered rows.

Four relatively adjacent third sub-pixels 3 may be one group, and each group of third sub-pixels includes four third sub-pixels 3 arranged side by side. Alternatively, the centers of the third sub-pixels 3 in the same row are on the same straight line. Moreover, in a same row of pixel units, the two third sub-pixels 3 with equal area and two third sub-pixels 3 with equal area adjacent thereto (i.e. one group of third sub-pixels) correspond to the same opening region of the metal mask (shown in the dashed box in the figure).

In this embodiment, the number of sub-pixels is also increased by splitting one of the sub-pixels of the pixel unit into two, and the distribution position of the sub-pixels in the pixel unit is adjusted, therefore the display effect is improved, and the display defects such as jaggies and black lines are greatly improved.

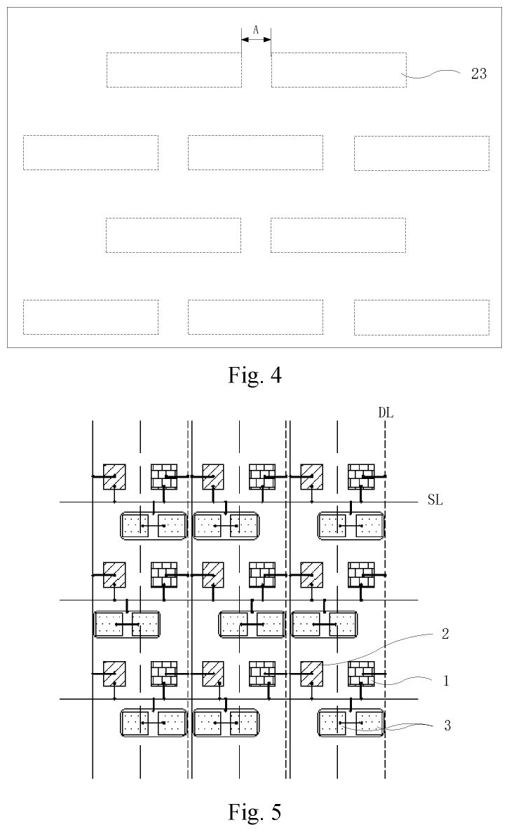

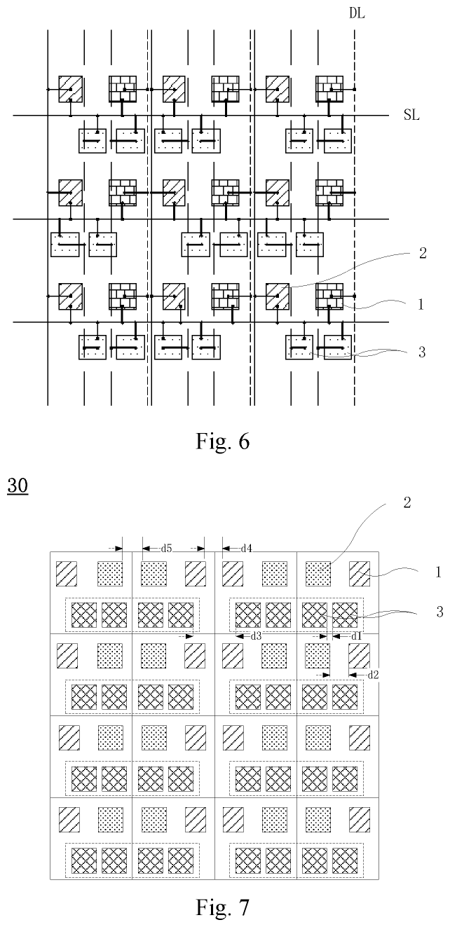

Correspondingly, the present disclosure also provides a metal mask. FIG. 4 is a schematic structural diagram of a metal mask according to the first embodiment of the present disclosure. As shown in FIG. 4, the metal mask includes: a substrate (the reference numeral is not shown in the figure); the substrate is provided with a plurality of opening regions 23, the plurality of opening regions 23 are arranged in sequence, and each opening region 23 corresponds to one group of the third sub-pixels 3 of the pixel arrangement structure 20 as mentioned above, and each group of the third sub-pixels 3 includes four adjacent third sub-pixels 3 with equal area.

Specifically, the metal mask is used for evaporating the third sub-pixels 3, and the positions of the plurality of opening regions 23 provided on the metal mask are adapted to the arrangement positions of the third sub-pixels 3.

In this embodiment, the third sub-pixel 3 is a blue sub-pixel, that is, the metal mask is used for evaporating the blue sub-pixel. In other embodiments, the third sub-pixel 3 may also be a red sub-pixel or a green sub-pixel, that is, the metal mask is used for evaporating the red sub-pixel or the green sub-pixel.

In the fabrication of metal mask, the spacing between the openings with the same color is one of the key factors for affecting the strength of the metal mask. As shown in FIG. 4, in the metal mask provided in this embodiment, since four third sub-pixels with equal area share the same opening region 23, it is possible to ensure that the spacing A between the openings with the same color is large enough to reduce the number of the opening regions 23 without sacrificing the strength of the metal mask. In this way, the difficulty of preparing the mask is reduced, and the restriction on the high-resolution screen due to the fabrication accuracy of the metal mask can be alleviated, thereby increasing the aperture ratio. Therefore, the service life of the organic light emitting display device can be lengthened and the imaging effect is more delicate.

In this embodiment, the metal mask is a fine metal mask (FMM), and the plurality of opening regions 23 of the metal mask are arranged side by side in the row direction and are arranged in a staggered arrangement in the column direction.

The metal mask provided in this embodiment also adopts the form of sharing the opening region to ensure the spacing between the openings with the same color, which reduces the number of the opening regions without sacrificing the strength of the FMM. In this way, the difficulty of preparing the mask is reduced, and the restriction on the high-resolution screen due to the fabrication accuracy of the FMM can be alleviated, thereby increasing the aperture ratio. The metal mask can be used to produce a display screen with more delicate imaging effect and longer service life.

Correspondingly, the present disclosure also provides an organic light emitting display apparatus, and the organic light emitting display apparatus includes the pixel arrangement structure 20 as described above. For details, the above contents may be referred to, which will not be repeated here.

In the pixel arrangement structure 20, each third sub-pixels group includes four blue sub-pixels, and the four blue sub-pixels are formed by evaporation through the same slot (i.e. the opening region 23).

This embodiment differs from the first embodiment in that the third sub-pixels 3 are arranged in a different way.

In the first embodiment, the arrangement of sub-pixels in each row of pixel units is kept the same, i.e., the arrangement of sub-pixels in odd-numbered rows is the same as the arrangement of sub-pixels in even-numbered rows. In the row and column directions of the array, the third sub-pixels 3 are all arranged side by side. Correspondingly, the opening regions 13 of the metal mask provided in the first embodiment are also arranged side by side in the row direction and the column direction.

In this embodiment, the arrangement of sub-pixels in each row of pixel units is not kept consistent, that is, the arrangement of sub-pixels in odd-numbered rows is not the same as the arrangement of sub-pixels in even-numbered rows. The third sub-pixels 3 in the odd-numbered rows and the third sub-pixels 3 in the even-numbered rows are staggered by a predetermined distance from each other, that is, the two third sub-pixels 3 with equal area are arranged side by side in the row direction of the array, and two third sub-pixels 3 with equal area are arranged in a staggered arrangement in the column direction of the array. Correspondingly, the opening regions 23 of the metal mask provided in this embodiment are arranged side by side in the row direction, and are arranged in a staggered arrangement in the column direction.

In the pixel arrangement structure 10 provided in the first embodiment, since the spacing between the third sub-pixels 3 (i.e., the blue sub-pixels) is relatively large, faint black lines may appear. However, in the pixel arrangement structure 20 provided in this embodiment, the spacing between the third sub-pixels 3 (i.e., the blue sub-pixels) is relatively small, so that the black line problem can be improved and the display performance is better.

Since the human eye is most sensitive to green light, if the relative position of the center of the green sub-pixel changes in the distribution of the pixels, a jagged display effect problem will occur. To this end, the green sub-pixel may be set as the third sub-pixel 3, and the positions of the two third sub-pixels 3 (i.e., the green sub-pixels) in the pixel unit can be adjusted for improvement.

In addition, two different panel driving manners, namely, single-line driving or dual-line driving may be adopted by the organic light emitting display apparatus with the pixel arrangement structure 20. As shown in FIG. 5, the horizontal solid line is the scanning signal line SL, and the vertical dotted line is the data signal line DL. The two third sub-pixels 3 of the same pixel unit (pixel) are connected in series and driven by the same data signal line DL, that is, the organic light emitting display apparatus adopts the single-line driving manner. As shown in FIG. 7, the horizontal solid line is the scanning signal line SL, and the vertical dotted line is the data signal line DL. The two third sub-pixels 3 of the same pixel unit (pixel) are driven by two data signal lines DL respectively, that is, the organic light emitting display apparatus adopts the dual-line driving manner, so that if one of the third sub-pixels 3 is damaged, the other third sub-pixel 3 can still support the pixel to emit light normally.

### Third Embodiment

FIG. 7 is a schematic structural diagram of a pixel arrangement structure according to a third embodiment of the present disclosure. As shown in FIG. 7, the pixel arrangement structure 30 includes a plurality of pixel units (reference numerals are not shown in the figure), the plurality of pixel units are arranged in an array in sequence, and each pixel unit (shown by a single solid line box) includes one first sub-pixel 1, one second sub-pixel 2 and two third sub-pixels 3 with equal area, where the two third sub-pixels with equal area are arranged in the same row and there is a first spacing d1 between the two third sub-pixels 3, and the first sub-pixel 1 and the second sub-pixel 2 are arranged in another adjacent row and there is a second spacing d2 between the first sub-pixel 1 and the second sub-pixel 2; where the first spacing d1 is smaller than the second spacing d2, a perpendicular bisector of a line connecting centers of the two third sub-pixels 3 with equal area does not overlap with a perpendicular center line of the pixel unit, the third sub-pixels 3 are all arranged in mirror symmetry in two laterally adjacent pixel units, the two third sub-pixels 3 with equal area and two third sub-pixels 3 adjacent thereto correspond to a same opening region of the metal mask, the third sub-pixels 3 corresponding to the same opening region of the metal mask are one group of the third sub-pixels 3, and a spacing d3 between adjacent two groups of the third sub-pixels 3 is greater than the second spacing d2.

Specifically, this embodiment differs from the first embodiment in that the first sub-pixels 1 and the second sub-pixels 2 are arranged in a different manner. As shown in FIG. 7, in the row direction of the array, the third sub-pixels 3 are arranged side by side, and the third sub-pixels are all arranged in mirror symmetry in two laterally adjacent pixel units. In the row direction of the array, the first sub-pixels 1 and the second sub-pixels 2 are not arranged alternately and repeatedly, but alternately arranged in pairs, that is, in two laterally adjacent pixel units, the first sub-pixels 1 and the second sub-pixels 2 are all arranged in mirror symmetry. Correspondingly, the opening positions of the metal mask for evaporating the first sub-pixels 1 and the metal mask for evaporating the second sub-pixels 2 should be adjusted accordingly.

In the first embodiment, each opening of the metal mask for evaporating the first sub-pixel 1 corresponds to one first sub-pixel 1, and each opening of the metal mask for evaporating the second sub-pixel 2 corresponds to one second sub-pixel 2. For the first sub-pixel 1 and the second sub-pixel 2, the spacing between adjacent sub-pixels of the same color is restricted by the shadow effect.

In this embodiment, however, each opening of the metal mask for evaporating the first sub-pixels 1 corresponds to two adjacent first sub-pixels 1, and each opening of the metal mask for evaporating the second sub-pixels 2 corresponds to two adjacent second sub-pixels 2. The metal mask for evaporating the third sub-pixels 3 remains unchanged, and four adjacent third sub-pixels 3 still share one opening.

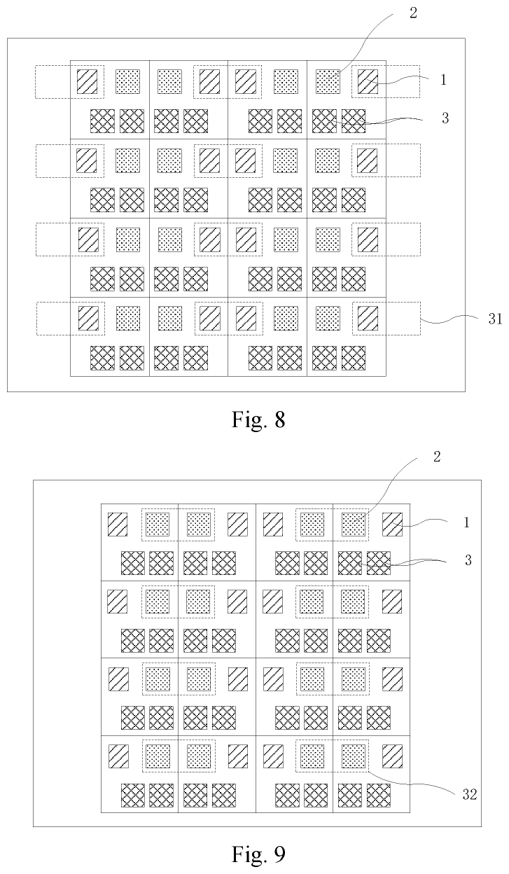

As shown in FIG. 8, on the metal mask for evaporating the first sub-pixels 1, the opening regions 31 are adapted to the arrangement positions of the first sub-pixels 1, and two adjacent first sub-pixels 1 share a same opening region 31 of the metal mask. As shown in FIG. 9, on the metal mask for evaporating the second sub-pixels 2, its opening regions 32 are adapted to the arrangement positions of the second sub-pixels 2, and two adjacent second sub-pixels 2 share a same opening region 32 of the metal mask. Since both the first sub-pixels 1 and the second sub-pixels 2 may share the opening of the metal mask in the row direction, in addition to that the spacing d1 between the third sub-pixels 3 is not affected by the shadow effect, the spacings between adjacent sub-pixels of the same color (including the spacing d4 between the first sub-pixels 1 and the spacing d5 between the second sub-pixels 2) are not restricted by the shadow effect, either, and the spacing between adjacent sub-pixels of the same color can be further reduced to increase the utilization rate of the corresponding space, thereby increasing the aperture ratio.

Correspondingly, the present disclosure also provides an organic light emitting display apparatus, and the organic light emitting display apparatus includes the pixel arrangement structure 30 as described above. For details, the above contents may be referred to, which will not be repeated here.

### Fourth Embodiment

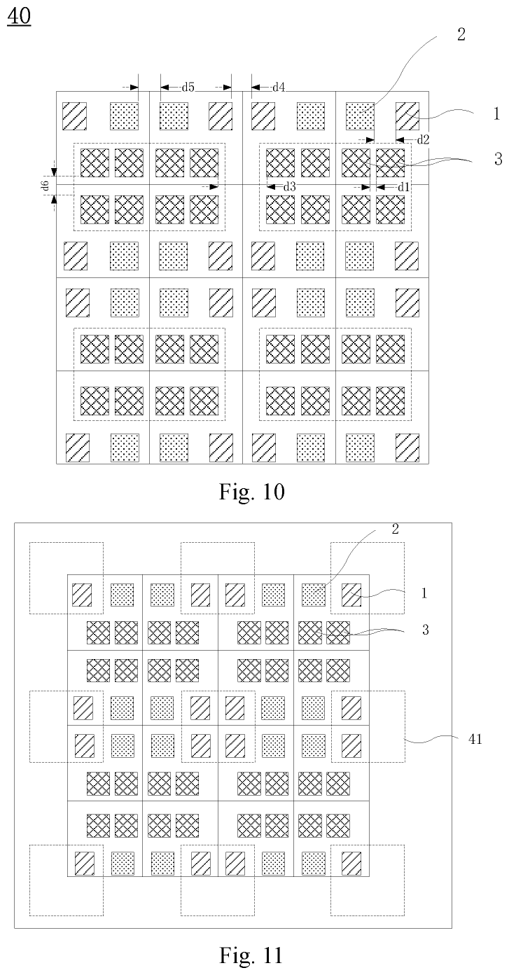

FIG. 10 is a schematic structural diagram of a pixel arrangement structure according to a fourth embodiment of the present disclosure. As shown in FIG. 10, the pixel arrangement structure 40 includes a plurality of pixel units (reference numerals are not shown in the figure), the plurality of pixel units are arranged in an array in sequence, and each pixel unit (shown by a single solid line box) includes one first sub-pixel 1, one second sub-pixel 2 and two third sub-pixels 3 with equal area, where the two third sub-pixels with equal area are arranged in the same row and there is a first spacing d1 between the two third sub-pixels 3, and the first sub-pixel 1 and the second sub-pixel 2 are arranged in another adjacent row and there is a second spacing d2 between the first sub-pixel 1 and the second sub-pixel 2; where the first spacing d1 is smaller than the second spacing d2, a perpendicular bisector of a line connecting centers of the two third sub-pixels 3 with equal area does not overlap with a perpendicular center line of the pixel unit, the third sub-pixels 3 are all arranged in mirror symmetry in two laterally adjacent pixel units, the two third sub-pixels 3 with equal area and six third sub-pixels 3 adjacent thereto correspond to a same opening region of the metal mask, the third sub-pixels 3 corresponding to the same opening region of the metal mask are one group of the third sub-pixels 3, and a spacing d3 between adjacent two groups of the third sub-pixels 3 is greater than the second spacing d2.

Specifically, this embodiment differs from the third embodiment in that the arrangement in the column direction is different. In the third embodiment, the sub-pixel rows formed by the first sub-pixels 1 and the second sub-pixels 2 and the sub-pixel rows formed by the third sub-pixels 3 are arranged alternately. However, in this embodiment, two sub-pixel rows formed by the first sub-pixels 1 and the second sub-pixels 2 and two sub-pixel rows formed by the third sub-pixels 3 are arranged alternately. As shown in FIG. 10, for two pixel units adjacent to each other laterally or vertically, the first sub-pixels 1, the second sub-pixels 2 and the third sub-pixels 3 are all arranged in mirror symmetry. That is, the two laterally adjacent pixel units are both arranged in mirror symmetry, and two vertically adjacent pixel units are both arranged in mirror symmetry. In this way, four first sub-pixels 1 are set adjacent to each other to share a same opening, four second sub-pixels 2 are set adjacent to each other to share a same opening, and eight third sub-pixels 3 are set adjacent to each other to share a same opening.

Correspondingly, the opening positions of the metal mask for evaporating the first sub-pixels 1, the opening positions of the metal mask for evaporating the second sub-pixels 2, and the opening positions of the metal mask for evaporating the third sub-pixel 3 should be adjusted accordingly. In this embodiment, each opening of the metal mask for evaporating the first sub-pixels 1 corresponds to four adjacent first sub-pixels 1, each opening of the metal mask for evaporating the second sub-pixels 2 corresponds to four adjacent second sub-pixels 2, and each opening of the metal mask for evaporating the third sub-pixels 3 corresponds to eight adjacent third sub-pixels 3.

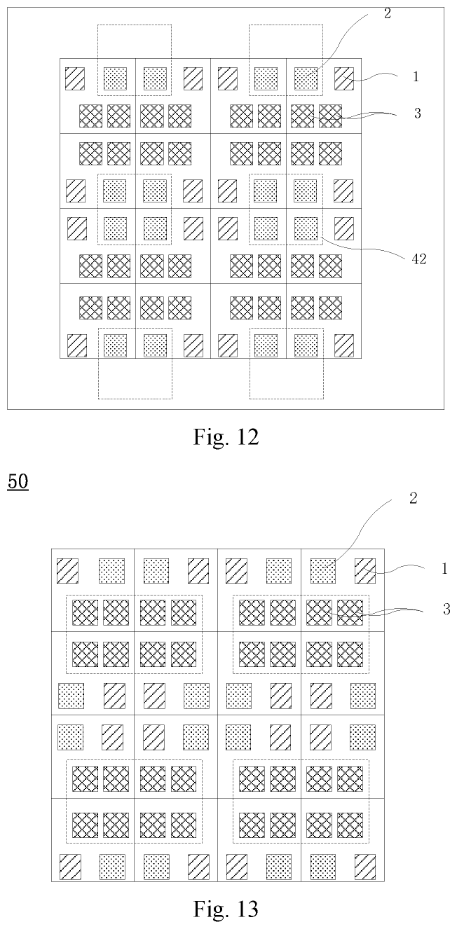

As shown in FIG. 11, on the metal mask for evaporating the first sub-pixels 1, its opening regions 41 are adapted to the arrangement positions of the first sub-pixels 1, and four adjacent first sub-pixels 1 share a same opening region 41 of the metal mask. As shown in FIG. 12, on the metal mask for evaporating the second sub-pixels 2, its opening regions 42 are adapted to the arrangement positions of the second sub-pixels 2, and four adjacent second sub-pixels 2 share a same opening region 42 of the metal mask. Since the first sub-pixels 1, the second sub-pixels 2 and the third sub-pixels may share the opening of the metal mask in both the row direction and the column direction, the lateral and vertical spacings between adjacent sub-pixels of the same color (including the spacing d4 between the first sub-pixels 1, the spacing d5 between the second sub-pixels 2, the lateral spacing d1 and the vertical spacing d6 between the third sub-pixels 3) are not restricted by the shadow effect, either, and the spacing between adjacent sub-pixels of the same color can be further reduced to increase the utilization rate of the corresponding space, thereby increasing the aperture ratio.

Correspondingly, the present disclosure also provides a metal mask. The metal mask includes: a substrate (the reference numeral is not shown in the figure); the substrate is provided with a plurality of opening regions (reference numerals are not shown in the figure), the plurality of opening regions are arranged in sequence, and each opening region corresponds to one group of the third sub-pixels 3 of the pixel arrangement structure 40 as mentioned above, and each group of the third sub-pixels 3 includes eight third sub-pixels 3 with equal area. The metal mask is used for evaporating the third sub-pixels 3.

Correspondingly, the present disclosure also provides an organic light emitting display apparatus, and the organic light emitting display apparatus includes the pixel arrangement structure 40 as described above. For details, the above contents may be referred to, which will not be repeated here.

### Fifth Embodiment

FIG. 13 is a schematic structural diagram of a pixel arrangement structure according to a fifth embodiment of the present disclosure. As shown in FIG. 13, the pixel arrangement structure 50 includes a plurality of pixel units (reference numerals are not shown in the figure), the plurality of pixel units are arranged in an array in sequence, and each pixel unit (shown by a single solid line box) includes one first sub-pixel 1, one second sub-pixel 2 and two third sub-pixels 3 with equal area, where the two third sub-pixels with equal area are arranged in the same row and there is a first spacing d1 between the two third sub-pixels 3, and the first sub-pixel 1 and the second sub-pixel 2 are arranged in another adjacent row and there is a second spacing d2 between the first sub-pixel 1 and the second sub-pixel 2; where the first spacing d1 is smaller than the second spacing d2, a perpendicular bisector of a line connecting centers of the two third sub-pixels 3 with equal area does not overlap with a perpendicular center line of the pixel unit, the third sub-pixels 3 are all arranged in mirror symmetry in two laterally adjacent pixel units, the two third sub-pixels 3 with equal area and six third sub-pixels 3 adjacent thereto correspond to a same opening region of the metal mask, the third sub-pixels 3 corresponding to the same opening region of the metal mask are one group of the third sub-pixels 3, and a spacing d3 between adjacent two groups of the third sub-pixels 3 is greater than the second spacing d2.

Specifically, this embodiment differs from the fourth embodiment in that the first sub-pixels 1 and the second sub-pixels 2 are arranged in a different way. Correspondingly, the opening positions of the metal mask for evaporating the first sub-pixels 1 and opening positions of the metal mask for evaporating the second sub-pixels 2 should be adjusted accordingly.

As shown in FIG. 13, in the row direction of the array, the first sub-pixels 1, the second sub-pixels 2 and the third sub-pixels 3 are all arranged in mirror symmetry, namely, the two laterally adjacent pixel units are all arranged in mirror symmetry. In the row direction of the array, the third sub-pixels 3 are still arranged in mirror symmetry, and the first sub-pixels 1 and the second sub-pixels 2 are not arranged in mirror symmetry. Rather, two vertically adjacent pixel units are arranged in mirror symmetry or one of the two vertically adjacent pixel units is arranged to overlap with the other pixel unit after being rotated by 180°. That is, the first sub-pixel group including four sub-pixels of the same color and the second sub-pixel group including four sub-pixels of the same color are arranged alternately in odd-numbered rows and even-numbered rows. Correspondingly, the opening positions of the metal mask for evaporating the first sub-pixels 1, the metal mask for evaporating the second sub-pixels 2, and the metal mask for evaporating the third sub-pixels 3 should be adjusted accordingly, so that the opening positions are also arranged alternately.

In this embodiment, the first sub-pixels 1, the second sub-pixels 2 and the third sub-pixels may also share the opening of the metal mask in both the row direction and the column direction, thus the lateral and vertical spacings between adjacent sub-pixels of the same color are not restricted by the shadow effect, and the spacing between adjacent sub-pixels of the same color can be further reduced to increase the utilization rate of the corresponding space, thereby increasing the aperture ratio.

Correspondingly, the present disclosure also provides an organic light emitting display apparatus, and the organic light emitting display apparatus includes the pixel arrangement structure 50 as described above. For details, the above contents may be referred to, which will not be repeated here.

### Sixth Embodiment

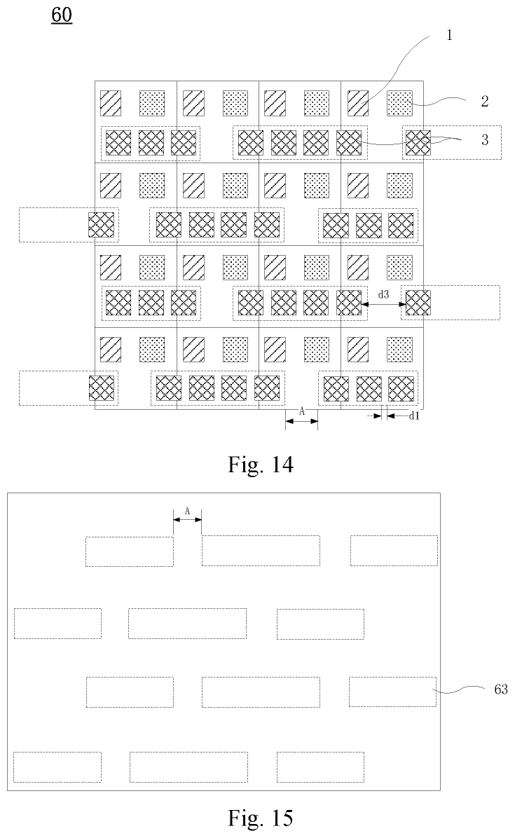

FIG. 14 is a schematic structural diagram of a pixel arrangement structure according to the sixth embodiment of the present disclosure. As shown in FIG. 14, the pixel arrangement structure 60 includes a plurality of pixel units (reference numerals are not shown in the figure), the plurality of pixel units are arranged in an array in sequence, and each pixel unit (shown by a single solid line box) includes one first sub-pixel 1, one second sub-pixel 2 and two third sub-pixels 3 with equal area, where the two third sub-pixels with equal area are arranged in the same row and there is a first spacing d1 between the two third sub-pixels 3, and the first sub-pixel 1 and the second sub-pixel 2 are arranged in another adjacent row and there is a second spacing d2 between the first sub-pixel 1 and the second sub-pixel 2; where the first spacing d1 is smaller than the second spacing d2, the two third sub-pixels 3 with equal area and at least one third sub-pixels 3 adjacent thereto correspond to a same opening region of the metal mask, the third sub-pixels 3 corresponding to the same opening region of the metal mask are one group of the third sub-pixels 3, and a spacing d3 between adjacent two groups of the third sub-pixels 3 is greater than the second spacing d2.

Specifically, this embodiment differs from the first embodiment in that the third sub-pixels 3 are arranged in a different manner. In the first embodiment, the spacings between the two third sub-pixels 3 of individual pixel units are equal, and the centers of the two third sub-pixels 3 are deviated from the center of the corresponding pixel unit, i.e., a perpendicular bisector of a line connecting centers of the two third sub-pixels 3 does not overlap with a perpendicular center line of the pixel unit. However, in this embodiment, the perpendicular bisector of the line connecting centers of the two third sub-pixels 3 overlaps with the perpendicular center line of the pixel unit, and the spacings of the two third sub-pixels 3 of individual pixel units are not consistent. In two horizontally adjacent pixel units, the spacing between two third sub-pixels 3 in one pixel unit is the spacing d3 between two adjacent groups of third sub-pixels 3, and the spacing between the two third sub-pixels 3 of the other pixel unit is the first distance d1. Since d3>d2>d1, the third sub-pixels 3 of one pixel unit are closer to the pixel unit on its right side, and the third sub-pixels 3 of the another pixel unit are closer to the pixel unit on its left side. Therefore, in the same row of pixel units, the two third sub-pixels 3 with equal area and one or two third sub-pixels 3 adjacent thereto may correspond to the same opening region of the metal mask.

Correspondingly, the present disclosure also provides a metal mask, which is used for evaporating the sub-pixels 3. FIG. 15 is a schematic structural diagram of a metal mask according to the sixth embodiment of the present disclosure. As shown in FIG. 15, the metal mask includes: a substrate (the reference numeral is not shown in the figure); the substrate is provided with a plurality of opening regions 63, the plurality of opening regions 63 are arranged in sequence, and each opening region 63 corresponds to one group of the third sub-pixels 3 of the pixel arrangement structure 60 as mentioned above, and each group of the third sub-pixels 3 includes four adjacent third sub-pixels 3 with equal area or three adjacent third sub-pixels 3 with equal area, since the plurality of third sub-pixels 3 share the same opening region 63, it can be ensured that the spacing A between the openings with the same color is large enough.

Correspondingly, the present disclosure also provides an organic light emitting display apparatus, and the organic light emitting display apparatus includes the pixel arrangement structure 60 as described above. For details, the above contents may be referred to, which will not be repeated here.

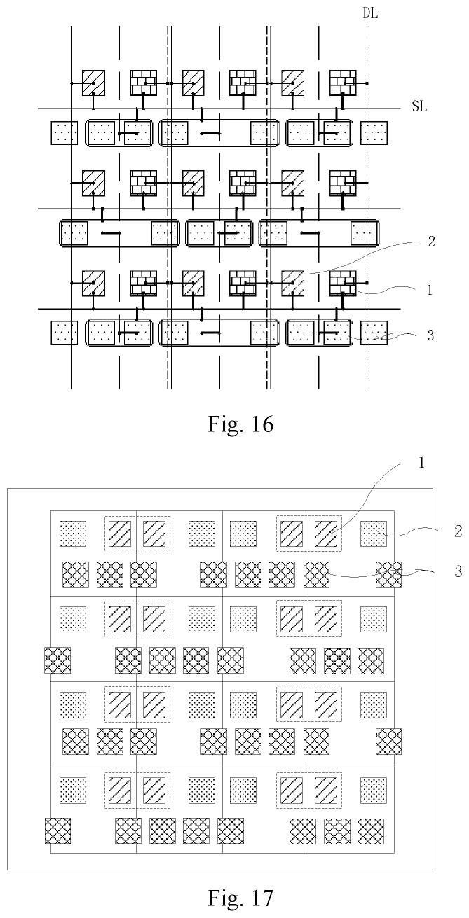

In addition, the single-line driving manner may be adopted by the organic light emitting display apparatus with the pixel arrangement structure 60. As shown in FIG. 16, the horizontal solid line is the scanning signal line SL, and the vertical dotted line is the data signal line DL. The two third sub-pixels 3 of the same pixel unit (pixel) are driven by the same data signal line DL.

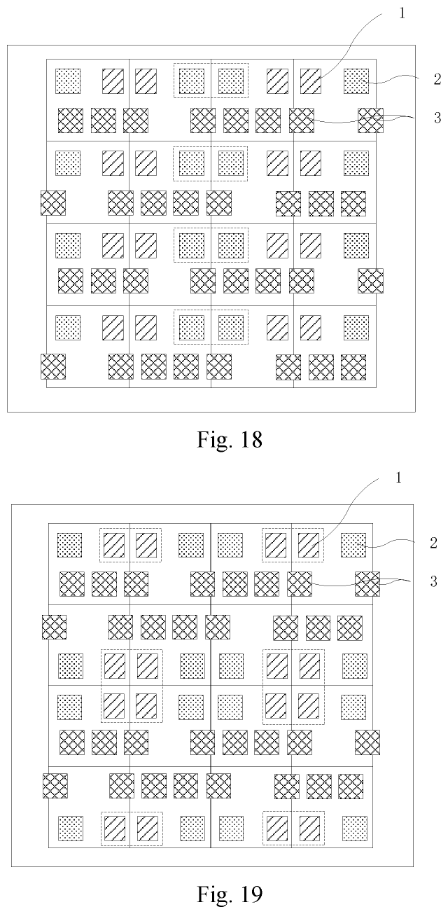

In other embodiments, other arrangement manners may also be adopted by the pixel arrangement structure 60. In the sixth embodiment, the first sub-pixels 1 and the second sub-pixels 2 in the same row are alternately and repeatedly arranged. In other embodiments, the arrangement manner of the third sub-pixels 3 is unchanged, but the first sub-pixels 1 and the second sub-pixels 2 in the same row are alternately arranged in pairs, so that both the first sub-pixels 1 and the second sub-pixels 2 may share the opening region of the metal mask. As shown in FIG. 17 and FIG. 18, in two laterally adjacent pixel units, the first sub-pixels 1 and the second sub-pixels 2 are all arranged in mirror symmetry, two adjacent first sub-pixels 1 or four adjacent first sub-pixels 1 correspond to the same opening region of the metal mask, and two adjacent second sub-pixels 2 correspond to the same opening region of the metal mask.

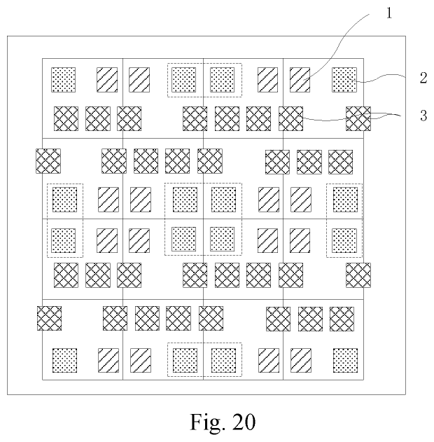

In the sixth embodiment, the sub-pixel rows formed by the first sub-pixels 1 and the second sub-pixels 2 and the sub-pixel rows formed by the third sub-pixels 3 are arranged alternately. In other embodiments, two sub-pixel rows formed by the first sub-pixels 1 and the second sub-pixels 2 and two sub-pixel rows formed by the third sub-pixel 3 are arranged alternately. As shown in FIG. 19 and FIG. 20, in two laterally or vertically adjacent pixel units, the first sub-pixels 1 and the second sub-pixels 2 are arranged in mirror symmetry. In this way, two or four adjacently arranged first sub-pixels 1 may share the same opening, and two or four adjacently arranged second sub-pixels 2 may share the same opening.

The above drawings merely schematically illustrate the pixel arrangement structure provided by the present disclosure. For the sake of clarity, the shapes and numbers of components in the above figures are simplified and some components are omitted. Those skilled in the art may make variations according to actual needs, and these variations are all within the scope of protection of the present disclosure and will not be repeated here.

It should be noted that the various embodiments in this specification are described in a progressive manner, each embodiment focuses on the differences from other embodiments, and the same and similar parts between the various embodiments may be referred to each other.

To sum up, in the pixel arrangement structure, the metal mask and the organic light emitting display apparatus provided by the present disclosure, the number of sub-pixels is increased by splitting one of the sub-pixels of the pixel unit into two, and the distribution position of the sub-pixels in the pixel unit is adjusted to improve the display effect, and the display defects such as jaggies and black lines are effectively improved. Moreover, the corresponding metal mask can ensure the spacing between the openings with the same color by using the form of sharing the opening region, thereby enhancing the strength of the metal mask, relieving the restriction of the manufacturing accuracy of the metal mask on the high-resolution screen, and improving the pixel aperture ratio. Thus, the display brightness and service life of the organic light emitting display apparatus are improved.

The above content is a further detailed description of the present application in conjunction with specific embodiments, and it cannot be considered that the specific implementation of the present application is limited to these descriptions. For those of ordinary skill in the art, without departing from the concept of the present application, some simple deductions or substitutions may be made, all of which should be regarded as falling within the scope of protection of this application.

1. A pixel arrangement structure, comprising:
a plurality of pixel units, wherein the plurality of pixel units are arranged in an array in sequence, each pixel unit comprises a first sub-pixel, a second sub-pixel and two third sub-pixels with equal area, the two third sub-pixels with equal area are arranged in a same row and have a first spacing, and the first sub-pixel and the second sub-pixel are arranged in another adjacent row and have a second spacing; and
wherein the first spacing is smaller than the second spacing, the two third sub-pixels with equal area and at least one third sub-pixel adjacent thereto correspond to a same opening region of a metal mask, the third sub-pixels corresponding to the same opening region of the metal mask are one group of the third sub-pixels, and a spacing between adjacent two groups of the third sub-pixels is greater than the second spacing.

2. The pixel arrangement structure according to claim 1, wherein a perpendicular bisector of a line connecting centers of the two third sub-pixels with equal area does not overlap with a perpendicular center line of the pixel unit, and the third sub-pixels are all arranged in mirror symmetry in two laterally adjacent pixel units.

3. The pixel arrangement structure according to claim 2, wherein in a same row of pixel units, the two third sub-pixels with equal area and two third sub-pixels adjacent thereto correspond to the same opening region of the metal mask.

4. The pixel arrangement structure according to claim 3, wherein in the same row of pixel units, the first sub-pixels and the second sub-pixels are arranged alternately and repeatedly; or
in the two laterally adjacent pixel units, the first sub-pixels and the second sub-pixels are all arranged in mirror symmetry.

5. The pixel arrangement structure according to claim 2, wherein in two adjacent rows of pixel units, the two third sub-pixels with equal area and six third sub-pixels adjacent thereto correspond to the same opening region of the metal mask.

6. The pixel arrangement structure according to claim 5, wherein the two laterally adjacent pixel units are both arranged in mirror symmetry, and two vertically adjacent pixel units are both arranged in mirror symmetry; or
the two laterally adjacent pixel units are both arranged in mirror symmetry, and one of the two vertically adjacent pixel units is arranged to overlap with the other pixel unit after being rotated by 180°.

7. The pixel arrangement structure according to claim 1, wherein a perpendicular bisector of a line connecting centers of the two third sub-pixels with equal area overlap with a perpendicular center line of the pixel unit, and in two laterally adjacent pixel units, the spacing between the two third sub-pixels in one pixel unit is greater than the spacing between the two third sub-pixels in the other pixel unit.

8. The pixel arrangement structure according to claim 7, wherein in a same row of pixel units, the two third sub-pixels with equal area and one or two third sub-pixels adjacent thereto correspond to the same opening region of the metal mask.

9. The pixel arrangement structure according to claim 1, wherein a spacing between the first sub-pixel and the second sub-pixel, a spacing between the first sub-pixel and the third sub-pixel, and a spacing between the second sub-pixel and the third sub-pixel are all equal.

10. The pixel arrangement structure according to claim 1, wherein the colors of the first sub-pixel, the second sub-pixel and the third sub-pixel are different from each other, and the first sub-pixel, the second sub-pixel and the third sub-pixel are respectively selected from any one of a red sub-pixel, a blue sub-pixel and a green sub-pixel.

11. The pixel arrangement structure according to claim 10, wherein the third sub-pixel is the blue sub-pixel or the green sub-pixel.

12. The pixel arrangement structure according to claim 1, wherein the pixel unit is a square, and the first sub-pixel, the second sub-pixel and the third sub-pixel are all rectangular, triangular, polygon or circle.

13. The pixel arrangement structure according to claim 1, wherein a ratio of an area of the third sub-pixel to an area of the first sub-pixel is between 0.5 and 1.5, and a ratio of the area of the third sub-pixel to an area of the second sub-pixel is between 0.5 and 1.5.

14. A metal mask, comprising:
a substrate, wherein the substrate is provided with a plurality of opening regions, the plurality of opening regions are arranged in sequence, each opening region corresponds to one group of third sub-pixels of a pixel arrangement structure,
wherein the pixel arrangement structure comprises:
a plurality of pixel units, wherein the plurality of pixel units are arranged in an array in sequence, each pixel unit comprises a first sub-pixel, a second sub-pixel and two third sub-pixels with equal area, the two third sub-pixels with equal area are arranged in a same row and have a first spacing, and the first sub-pixel and the second sub-pixel are arranged in another adjacent row and have a second spacing; and
wherein the first spacing is smaller than the second spacing, the two third sub-pixels with equal area and at least one third sub-pixel adjacent thereto correspond to a same opening region of a metal mask, the third sub-pixels corresponding to the same opening region of the metal mask are the one group of third sub-pixels, and a spacing between adjacent two groups of the third sub-pixels is greater than the second spacing, and
each group of the third sub-pixels comprises four third sub-pixels with equal area or eight third sub-pixels with equal area.

15. The metal mask according to claim 14, wherein the plurality of opening regions are arranged side by side in both a row direction and a column direction; or
the plurality of opening regions are arranged side by side in the row direction, and are arranged in a staggered arrangement in the column direction.

16. An organic light emitting display apparatus, comprising: a pixel arrangement structure,
wherein the pixel arrangement structure comprises:
a plurality of pixel units, wherein the plurality of pixel units are arranged in an array in sequence, each pixel unit comprises a first sub-pixel, a second sub-pixel and two third sub-pixels with equal area, the two third sub-pixels with equal area are arranged in a same row and have a first spacing, and the first sub-pixel and the second sub-pixel are arranged in another adjacent row and have a second spacing; and
wherein the first spacing is smaller than the second spacing, the two third sub-pixels with equal area and at least one third sub-pixel adjacent thereto correspond to a same opening region of a metal mask, the third sub-pixels corresponding to the same opening region of the metal mask are one group of the third sub-pixels, and a spacing between adjacent two groups of the third sub-pixels is greater than the second spacing.

17. The organic light emitting display apparatus according to claim 16, wherein the two third sub-pixels of a same pixel unit are both driven by a same data signal line; or
the two third sub-pixels of the same pixel unit are respectively driven by two data signal lines.

18. The organic light emitting display apparatus according to claim 16, wherein a perpendicular bisector of a line connecting centers of the two third sub-pixels with equal area does not overlap with a perpendicular center line of the pixel unit, and the third sub-pixels are all arranged in mirror symmetry in two laterally adjacent pixel units.

19. The organic light emitting display apparatus according to claim 17, wherein in a same row of pixel units, the two third sub-pixels with equal area and two third sub-pixels adjacent thereto correspond to the same opening region of the metal mask.

20. The organic light emitting display apparatus according to claim 18, wherein in the same row of pixel units, the first sub-pixels and the second sub-pixels are arranged alternately and repeatedly; or
in the two laterally adjacent pixel units, the first sub-pixels and the second sub-pixels are all arranged in mirror symmetry.
